(19) United States
(12) Patent Application Publication
(10) Pub. No.: US 2009/0199763 A1
(43) Pub. Date: Aug. 13, 2009

(54) Process for the production of gan or aigan crystals

(76) Inventors: Armin Dadgar, Berlin (DE); Alois Krost, Berlin (DE)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 11/665,514

(22) PCT Filed: Oct. 17, 2005
(86) PCT No.: PCT/EP05/55320

§ 371 Date: Apr. 13, 2007

(30) Foreign Application Priority Data
Oct. 16, 2004 (DE) 10 2004 050 806.2

(51) Int. Cl. C30B 23/06; C23C 16/02

(52) U.S. Cl. 117/88; 118/726; 118/722; 117/103

(57) ABSTRACT

The invention concerns a process and an apparatus for the production of gallium nitride or gallium aluminium nitride single crystals. It is essential for the process implementation according to the invention that the vaporisation of gallium or gallium and aluminium is effected at a temperature above the temperature of the growing crystal but at least at 1000° C. and that a gas flow comprising nitrogen gas, hydrogen gas, inert gas or a combination of said gases is passed over the surface of the metal melt in such a way that the gas flow over the surface of the metal melt prevents contact of the nitrogen precursor with the metal melt.

### CROSS REFERENCE TO RELATED APPLICATIONS

This application is for entry into the U.S. national phase under §371 for International Application No. PCT/EP2005/055320 having an international filing date of Oct. 17, 2005, and from which priority is claimed under all applicable sections of Title 35 of the United States Code including, but not limited to, Sections 120, 363 and 365(c), and which in turn claims priority under 35 USC §119 to German Patent Application No. 102004050806.2 filed Oct. 16, 2004.

### BACKGROUND OF THE INVENTION

1. Technical Field

The invention concerns a process and a reactor arrangement for the production of a gallium nitride crystal or an aluminium gallium nitride crystal.

2. Discussion of Related Art

Single crystals of group III nitride compounds can be used as high-grade, low-dislocation substrates for group III nitride semiconductor epitaxy, in particular for blue or UV lasers. At the present time however such substrates are only limitedly available and are extremely costly: production is restricted to small areas or, in the case of pseudosubstrates which are produced by means of hydride gaseous phase epitaxy on foreign substrates, is limited to a few millimetres in thickness due to the procedure involved. The result of this is that low-dislocation substrates can be produced only at a high level of complication and expenditure and are correspondingly costly. Growth out of a melt, for example similarly to the liquid encapsulated Czochralski method in the case of GaAs has not been successful hitherto and is also not possible in the foreseeable future by virtue of the very high nitrogen vapour pressures which occur over a melt.

In contrast single crystals of AIN are primarily produced at the present time by means of sublimation procedures at very high pressures. For that purpose AIN powder is heated, sublimated and diffuses to the colder end of the growth chamber where an AIN crystal then grows. Disadvantages here are difficulties in scalability, the high level of contamination of the single crystal and the crystals which are always still very small and which can be only limitedly used for epitaxy. Direct growth from aluminium vapour and NH₃ is already described for example by Witzke, H-D: Über das Wachstum von AIN Einkristallen, Phys Stat sol 2, 1109 (1962) and Paster\check{n}ák J and Roskovcová L: Wachstum von AIN Einristallen, Phys Stat sol 7, 331 (1964). Here a large number of small single crystals were grown, which are suitable for fundamental research in material sciences, but are not suitable for epitaxy of structural elements. Group III nitride epitaxy of semiconductor lasers necessitates first and foremost GaN substrates in respect of which a similar process is simply not possible as that involves the troublesome formation of GaN on the gallium melt, as described for example by Balkas, C M et al: Growth and Characterization of GaN Single Crystals, Journal of Crystal Growth 208, 100 (2000), Elwell, D et al: Crystal Growth of GaN by the Reaction between Gallium and Ammonia, Journal of Crystal Growth 66, 45 (1984), or Ejder E: Growth and Morphology of GaN, Journal of Crystal Growth 22, 44 (1974). Elwell et al mentions in particular a surface reaction which was always observed between metallic gallium and ammonia, with the result that small crystals grow on the gallium melt and also at reactor parts covered by gallium.

At the present time so-called pseudosubstrates are produced for the growth of semiconductor lasers on GaN, by means of hydride gaseous phase epitaxy procedures, such as for example in the case of one of the largest manufacturers of such substrates, Sumitomo of Japan, see JP002004111865AA. Here the gallium metal reacts in a region separated from the nitrogen precursor ammonia to provide gallium chloride by passing chlorine thereover, which then in turn reacts over a substrate with ammonia to give GaN and ammonium chloride. The latter compound is extremely problematical in terms of crystal growth as it occurs in large amounts and as a solid can cover or clog the reaction chamber and the exhaust gas system and often interferes with the crystal growth due to severe particle formation.

Alternatively GaN wafers are produced at high pressures and temperatures from a gallium melt, see U.S. Pat. No. 6,273,948 B1 and Grzegory, I et al: Mechanisms of Crystallization of Bulk GaN from the Solution under high N₂ Pressure, Journal of Crystal Growth 246, 177 (2002). In this case however sizes adequate for commercial exploitation have hitherto not been achieved and the crystals in part present high levels of oxygen concentration, which admittedly makes them highly conductive but which makes them susceptible to lattice defects in comparison with high-purity epitaxial GaN. The production of GaN single crystals directly from or in metal melts (U.S. Pat. No. 6,592,663 B1), in part with the result of relatively large but thin single crystals, is also known, but hitherto could not prove successful probably because of the reported high levels of carbon inclusions (see Soukhoveev, V et al: Characterization of 2.5-Inch Diameter Bulk GaN Grown from Melt-Solution, phys stat sol (a) 188, 411 (2001)) and the slight layer thickness.

The slight progress made in the study of the production of GaN single crystals, extending over 40 years, is astonishing in that respect. In that connection, as already mentioned, most works are concerned with the production of crystals from melts or from the gaseous phase by the reaction of gallium chloride and ammonia. Few works are concerned with the reaction of molten gallium and a reactive nitrogen precursor such as for example ammonia and then always involving direct contact of the substances at the melt such as for example in the works by Shin, H et al: High temperature nucleation and growth of GaN crystals from the vapor phase, Journal of Crystal Growth, 241, 404 (2002); Balkas, C M et al: Growth and Characterization of GaN Single Crystals, Journal of Crystal Growth 208, 100 (2000); Elwell, D et al: Crystal Growth of GaN by the Reaction between Gallium and Ammonia, Journal of Crystal Growth 66, 45 (1984); or Ejder, E: Growth and Morphology of GaN, Journal of Crystal Growth 22, 44 (1974). Shin describes that a crust is formed on the gallium melt, which interferes with the crystal growth due to droplet formation, caused thereby, of the gallium on surrounding walls. In particular, with those methods a large number of small crystals are always produced in the reaction chamber and the crystal growth is for the major part uncontrolled and is therefore not suitable for large single crystals but is suitable for small, very high-grade crystals for research applications.

JP 11-209 199 A discloses a reactor arrangement for the production of GaN single crystals with what is referred to as a hot wall process. A disadvantage of the process described therein, for use on a large technical scale, is an excessively low level of attainable growth rate for the single crystal.

The underlying technical problem of the present invention is to provide a process and a reactor arrangement for the production of gallium nitride crystals or aluminium gallium nitride crystals, which permits crystal growth by the reaction of molten gallium with a reactive nitrogen precursor without crust formation on the gallium melt and the problems involved therewith in terms of crystal growth and with an improved growth rate.

### DISCLOSURE OF INVENTION

A first aspect of the present invention concerns a process for the production of a gallium nitride crystal or an aluminium gallium nitride crystal. The process comprises the steps:
providing a metal melt of pure gallium or a mixture of aluminium and gallium in a melting crucible;
vaporisation of gallium or gallium and aluminium out of the metal melt;
decomposing a nitrogen precursor by thermal effect or by means of a plasma; and
causing single-crystalline crystal growth of a GaN or AlGaN crystal on a seed crystal under a pressure of less than 10 bars.

The vaporisation of gallium or gallium and aluminium is effected at a temperature above the temperature of the growing crystal but at least at 1000° C.

The process according to the invention provides that a gas flow of nitrogen gas, hydrogen gas, inert gas or a combination of those gases is passed over the metal melt surface in such a way that the gas flow over the metal melt surface prevents contact of the nitrogen precursor with the metal melt.

The process according to the invention forms an alternative to the growth of gallium nitride or aluminium gallium nitride by liquid phase hydride epitaxy processes or by the simple reaction of gallium vapour and ammonia. The process according to the invention provides that pure metal is vaporised and transported in a gas flow into a reaction region where single-crystalline crystal growth of a GaN or AlGaN crystal is produced on a seed crystal. The problem of the low vapour pressure of gallium is overcome with the process according to the invention in that a temperature of at least 1000° C., which is suitable for appropriate growth rates of the crystal, is set for the vaporisation of gallium or gallium and aluminium.

Furthermore the process according to the invention resolves the problem of the direct reaction of gallium with the nitrogen precursor, that is frequently observed, insofar as a gas flow of nitrogen gas, hydrogen gas, inert gas or a combination of those gases is passed over the metal melt surface, more specifically in such a way that the gas flow over the metal melt surface prevents the nitrogen precursor from coming into contact with the metal melt. In this case different operative mechanisms can be used depending on the respective gas employed. An inert gas such as for example helium, argon or nitrogen (N₂) can prevent the contact between the melt and the nitrogen precursor when the gas flow is suitably guided and involves a suitable flow speed. Depending on the respective reactor pressure and the flow speeds involved on the other hand, when using nitrogen gas, a crystalline GaN or AlGaN layer which is being formed on the melt can be broken down by virtue of the high reactivity of the hydrogen which occurs at the high temperature of the melt, thereby ensuring further vaporisation of the metal.

Nitrogen gas is referred to here separately from the inert gases although it has properties of an inert gas, namely it does not involve any chemical reaction with the metal of the melt (or with the nitrogen precursor). That applies however only at lower temperatures at which nitrogen is present in molecular form (N₂). At temperatures of the metal melt of for example 1400° C., which are also embraced by the process according to the invention, nitrogen is present in atomic form and in principle can react with gallium and therefore does not form an inert gas. At such high temperatures however atomic nitrogen can nonetheless be passed over the metal melt without having to tolerate crusting because GaN is not stable in that temperature range.

A combination of the two specified operative mechanisms is also possible, insofar as a gas flow which contains both hydrogen gas and also an inert gas is passed over the metal melt surface, or insofar as a plurality of gas flows are passed over the metal melt surface, wherein one gas flow is formed by inert gas and another gas flow is formed by gas containing or consisting of hydrogen.

The process according to the invention provides that uniform growth of a single crystal is promoted on a large area, by the growth beginning on a seed crystal. In that fashion, the process according to the invention permits the production of gallium nitride or aluminium gallium nitride substrates.

Alternatively however the seed crystal can also be designed for a small surface area. A GaN rod then grows first. That is helpful for reducing dislocation concentrations which initially are inevitably high. A clever choice in respect of the gas composition, in particular the V/III ratio, and the pressure can then promote lateral growth on a desired diameter and ultimately can provide for the growth of a long GaN rod of a diameter which is also adequate for substrate production.

In comparison with the known hydride epitaxy process the process according to the invention has the advantage of not producing any troublesome deposits. In the case of hydride epitaxy for example the use of gallium chloride and ammonia causes the production of ammonium chloride deposits which impede the growth of large crystals.

As a result therefore the described method is ideally suited for the mass production of large single crystals from which substrates for the epitaxy of group III nitrides can later be produced by sawing and polishing. Furthermore the process according to the invention, by virtue of the crystal size which can be achieved, minimises reaction wear, as is the rule with hydride gas phase epitaxy in quartz glass reactors. For, in hydride gaseous phase epitaxy, the growing layer tears away the quartz glass used at the latest when cooling takes place. The pseudosubstrates produced with hydride gaseous phase epitaxy are therefore very expensive to produce. In contrast, the process described here means that a large number of substrates can be sawn from a crystal, even if an inner covered part of the reactor breaks off. The price per substrate can be markedly reduced in that way.

The process according to the invention is limited in terms of crystal size solely by the temperature homogeneity at the location of crystal growth and by the amount of molten gallium. As gallium is liquid from 27° C. however gallium can be refilled by a feed thereof during operation, that is to say in production of the crystal.

Embodiments of the process according to the invention are described hereinafter.

An embodiment of the process according to the invention provides that the metal melt is provided in a melting crucible vessel which, apart from at least one carrier gas feed and at least one carrier gas outlet opening, is closed on all sides. In this embodiment the gas flow is introduced into the melting crucible vessel through the carrier gas feed above the metal melt and transported with metal vapour of the metal melt out of the melting crucible vessel through the carrier gas outlet opening.

This embodiment affords an increased level of protection from crust formation on the surface of the metal melt, supplemental to the gas flow, insofar as the melting crucible vessel is closed on all sides except for the described gas feed and discharge means. In that way the structural configuration of the crucible ensures that reaction of the molten metal does not take place on the surface of the metal melt but only in the reaction region provided for that purpose near the seed crystal or the growing single crystal. Furthermore, the closed structural configuration of the melting crucible provides advantageous flow conditions for transport of the metal atoms vaporised out of the metal melt, towards the growing crystal.

In an alternative embodiment the provision of the metal melt includes arranging the melting crucible in a reactor chamber, wherein here at least one carrier gas feed into the reactor chamber is provided. In this embodiment the gas flow is introduced into the reactor chamber through the carrier gas feed slightly above the metal melt. The nitrogen precursor is introduced into the reactor chamber through the precursor inlet opening in a reaction region. In comparison with the preceding embodiment this embodiment substantially dispenses with the surface of the metal melt being covered over by the structural configuration of the melting crucible, and with the carrier gas feed into the melting crucible. The melting crucible can therefore be produced in a particularly simple and inexpensive fashion.

In both alternative process implementations, the gas flow is introduced into the melting crucible vessel or into the reactor chamber either in a direction in parallel relationship with the surface of the metal melt or in a direction in perpendicular relationship with the surface of the metal melt.

In a further preferred embodiment of the process the vaporisation of gallium or gallium and aluminium is effected at a temperature of at least 1100° C. The metal vapour pressure which is increased thereby can be used to accelerate crystal growth.

Various substances can be introduced into the reactor chamber for specifically targeted doping of the growing single crystals. In a first alternative that can be effected by the introduction of a gaseous precursor, silicon or germanium hydride compounds such as for example silane, germane, disilane or digermane can be used for n-type doping. Metallorganic compounds such as for example tertiary butyl silane are also suitable for doping. A corresponding consideration also applies to p-doping. Magnesium is predominantly suitable here, which can be passed into the reaction chamber with a carrier gas very easily, for example in the form of metallorganic cyclopentadienyl magnesium. For example iron in the form of cyclopentadienyl iron, also known as ferocene, or other transition metals which produce low impurity levels as far as possible in the middle of the band gap of the semiconductor crystal produced are suitable for the production of high-ohmic crystals.

A second alternative process implementation for doping provides that a dopant such as for example silicon, germanium, magnesium or iron is vaporised as pure melt, or the respective solid is sublimated. For that purpose, a further temperature zone or a separately heated crucible is required in the reactor. In most cases, similarly to the gallium-bearing melt, that crucible also has to be protected from nitriding, which can be effected in a quite similar fashion to the process implementation using the melting crucible of the group III metal by a gas flow.

In an embodiment in which the gas flow contains or consists of hydrogen the provision of the metal melt in a melting crucible preferably includes the use of a melting crucible of boron nitride BN, tantalum carbide TaC, silicon carbide SiC, quartz glass or carbon or a combination of two or more of those materials. Experience has shown that a crucible made solely from carbon disintegrates after a few hours of operation with a hydrogen feed. In that case therefore a carbon crucible should be coated with one of the other materials specified.

A second aspect of the invention is formed by a reactor arrangement for the production of a gallium nitride crystal or a gallium aluminium nitride crystal. The reactor arrangement according to the invention includes
a device for feeding a nitrogen precursor into a reaction region of a reactor chamber,
a device for decomposition of the nitrogen precursor in the reaction region by thermal action or by means of a plasma,
a melting crucible for receiving a metal melt of pure gallium or a mixture of aluminium and gallium,
a first heating device which is adapted to set the temperature of the metal melt in the melting crucible to a value above the temperature of the growing crystal but at least at 1000° C.,
a carrier gas source which is adapted to deliver nitrogen gas, hydrogen gas, inert gas or a combination of said gases, and
at least one carrier gas feed which is connected to the carrier gas source and which is arranged and adapted to pass a gas flow over the metal melt surface in such a way that the gas flow prevents contact of the nitrogen precursor with the metal melt.

The advantages of the reactor arrangement according to the invention arise directly out of the above-described advantages of the process according to the invention.

Preferred embodiments by way of example of the reactor arrangement are described hereinafter. A detailed representation will be waived insofar as embodiments directly represent an apparatus aspect of an embodiment, already described in detail hereinbefore, of the process in accordance with the first aspect.

In an embodiment of the reactor arrangement according to the invention the melting crucible is in the form of a melting crucible vessel which, apart from the carrier gas feed and at least one carrier gas outlet opening, is closed on all sides. The carrier gas feed is arranged above the surface of the metal melt.

In a variant of this embodiment the first heating device is adapted to heat the walls of the melting crucible vessel above the metal melt to a higher temperature than in the region of the metal melt. That prevents droplets being formed in the rising metal vapour, which droplets can also be deposited in the melting crucible or at the walls of the reactor chamber outside the melting crucible.

Instead of a heating device which produces different temperature ranges it is also possible to provide two heating devices. In this embodiment the carrier gas outlet opening can form the end of a tubular outlet. A second heating device is then adapted to heat the walls of the tubular outlet to a higher temperature than the first heating device heats the walls of the melting crucible vessel in the region of the metal melt.

In different embodiments, the carrier gas feed is adapted to introduce a gas flow into the melting crucible vessel or the reactor chamber in a direction in parallel relationship with the surface of the metal melt or in perpendicular relationship with the surface of the metal melt. It is also possible to provide a plurality of feeds, of which one provides for introduction in perpendicular relationship to the surface of the melt and another provides for introduction in parallel relationship with the surface of the melt.

Various alternative configurations of the carrier gas feed are described in greater detail hereinafter with reference to the Figures.

It is preferable, in particular for the use of hydrogen gas, for the melting crucible to be made from boron nitride BN, tantalum carbide TaC, silicon carbide SiC, quartz glass or carbon, or a combination of two or more of those materials.

For the growth of GaAl crystals, it is possible to provide a melting crucible for a corresponding metal mixture, as described. Alternatively, two separate melting crucibles can also be arranged in the reactor chamber, of which one contains a gallium melt and the other an aluminium melt. In this embodiment, the ratio of the two metals in the growing crystal can be adjusted by separate setting of the two melting crucible temperatures and by the respective carrier gas flow into the two crucibles.

### BRIEF DESCRIPTION OF THE DRAWINGS

Further embodiments of the process according to the invention and the reactor arrangement according to the invention are described hereinafter with reference to the accompanying Figures in which:

FIG. 1 is a diagrammatic view of a first embodiment of a reactor arrangement,

FIGS. 2-8 show various alternative configurations of melting crucibles for use in a reactor arrangement according to the invention, and

FIG. 9 shows a second embodiment of a reactor arrangement for the production of a GaN or AlGaN crystal.

### DETAILED DESCRIPTION

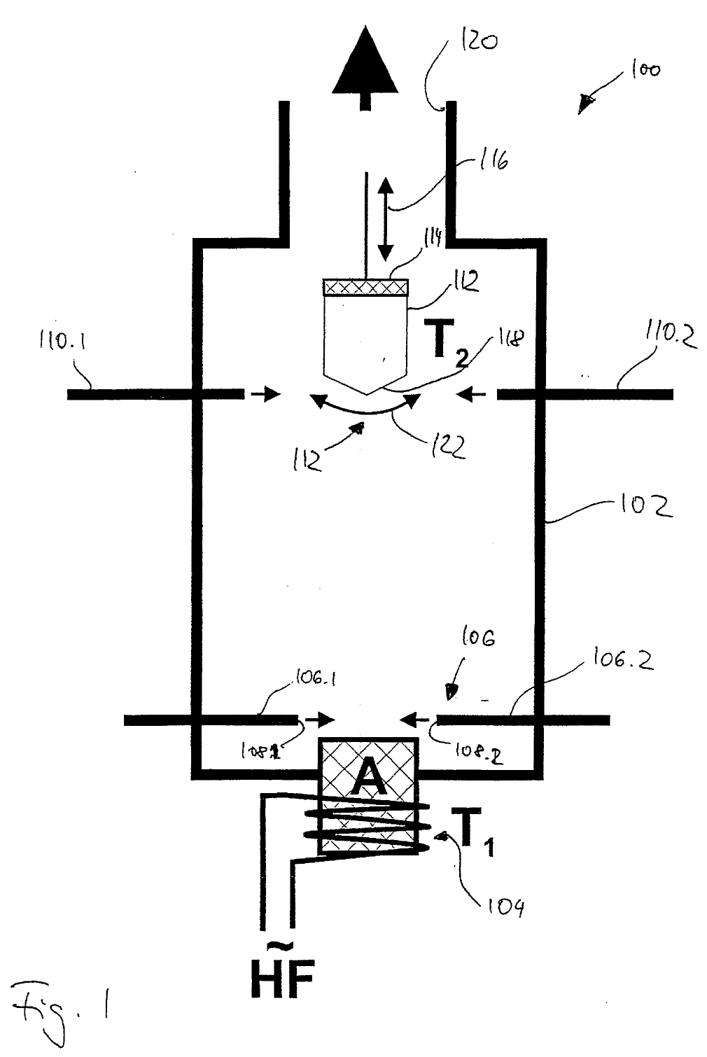

FIG. 1 shows a simplified diagrammatic view of a first embodiment of a reactor arrangement 100. The reactor arrangement 100 is a vertical reactor. In a lower portion thereof, a reactor vessel 102 contains a melting crucible A which contains a gallium melt (not shown). A high frequency heating means 104 heats the gallium melt by means of a high-frequency electrical alternating field. A high frequency heating means of that kind is ideally suitable for achieving a high temperature to over 2000° C. because it operates with a low level of maintenance and in contact-free fashion. Disposed just above the melting crucible is a carrier gas feed 106 in the form of gas lines 106.1 and 106.2 which are arranged at the same height and in opposite relationship, that is to say with their openings facing towards each other. Outlet openings 108.1 and 108.2 are arranged at a small lateral spacing from the melting crucible A. As the melting crucible A is open upwardly that arrangement of the carrier gas feed 106 can produce a gas flow which is guided directly over the surface of the metal melt.

The nitrogen precursor is introduced through precursor feed lines 110.1 and 110.2 into a reaction region 112 which is disposed just below a gallium nitride crystal 112 growing on the basis of an originally present seed crystal. The gallium nitride crystal is fixed to a holder 114 which can be controlledly displaced in the vertical direction (indicated by a double-headed arrow 116) by means of a suitable adjusting device (not shown). That is effected on the one hand for introducing the seed crystal into the reactor chamber and on the other hand for holding the currently prevailing growth surface of the crystal being formed, at the same vertical position.

In the arrangement shown in FIG. 1 the gas flow caused by the carrier gas feed lines 106.1 and 106.2 provides for transport of gallium-rich vapour out of the region of the metal melt in the melting crucible A in the direction of the growing crystal 112. That is necessary first and foremost in operation under high pressure as otherwise the gallium vapour is propagated only by diffusion. If the reactor walls were colder, gallium vapour would be deposited there so greatly that, depending on the respective spacing between the melting crucible A and the crystal 112, the gallium vapour does not reach the crystal at all or reaches it only in a reduced amount.

Besides the gas inlets 106.1 and 106.2 shown in FIG. 1 the carrier gas feed 106 can include further gas inlets through which a further gas flow is produced in the lower part of the reaction chamber 102, which further gas flow can alter the gas mixture. The introduction of gas through the feed line 106.1 and 106.2 crucially controls the composition of the gas atmosphere in the region of the melting crucible A. The gases H₂ and N₂ which are available in a high level of purity are most suitable. In the present example for example the ratio of H₂ and N₂ could be altered by means of further gas inlets, whereby the crystal growth can be specifically targetedly influenced and in addition deposits at the walls of the reactor chamber 102 can also be reduced.

In that respect, in the present embodiment of a vertical reactor, it is advantageous that the outlet openings are arranged in mutually opposite relationship. Transport of the gallium vapour upwardly is improved in that way.

As an alternative to the illustrated arrangement of the precursor feed lines 110.1 and 110.2, they can also be arranged above the growth surface 118 of the crystal 112 being produced. In that case the nitrogen precursor then diffuses against the gas flow which leads to an outlet 120 at the upper end of the reactor chamber to the growth front 118 at the lower end of the crystal. The lateral and vertical crystal growth can be controlled to a slight degree by the vertical position of the nitrogen feeds 110.1 and 110.2.

Various substances can be introduced into the reactor chamber for specifically targeted doping of the growing single crystals. That can be done by the introduction of a gaseous precursor. Silicon or germanium hydride compounds such as for example silane, germane, disilane or digermane can be used for n-type doping. Metallorganic compounds such as for example tertiary butyl silane are also suitable for doping and can be introduced into the reaction chamber for n-doping. A corresponding consideration applies to p-doping. Predominantly magnesium is appropriate here, which can be very easily introduced into the reaction chamber, for example in the form of metallorganic cyclopentadienyl magnesium, with a carrier gas. For high-ohmic layers for example iron in the form of cyclopentadienyl iron, also known as ferocene, is also appropriate, or other transition metals which produce deep impurity levels as far as possible in the middle of the band gap. Another possibility involves vaporising the dopants such as for example silicon, germanium, magnesium or iron as pure melts, or sublimating the respective solid. A further temperature zone or a separately heated crucible in the reactor is required for that purpose. In most cases, similarly to the gallium-bearing melt, that crucible also has to be protected from nitriding.

The growing crystal 112 or the reactor chamber in the upper part thereof are heated to a temperature T₂ which is at about 1000° C. and which is effected for example by heating of the reactor wall by means of an externally disposed resistance heater (not shown) or a lamp heating means (also not shown). In the lower region of the reactor chamber 102 it is recommended that the reactor wall is heated to a similar or somewhat higher temperature like the temperature of the melting crucible (T1) in order to prevent excessively severe deposit of gallium on the reactor wall.

The growth speed in various crystal directions can be increased or inhibited as required by the gas composition, that is to say the ratio of for example H₂, N₂, as well as the nitrogen precursor, and by the growth temperature and the reactor pressure, so that it is possible to achieve specific crystal orientations and crystal shapes.

By way of example a thin GaN layer on a foreign substrate serves as the seed crystal. Dislocations are increasingly reduced in the course of the growth of a thicker crystal. The growing crystal can be rotated (indicated by the double-headed arrow 122) to increase the homogeneity of growth and should be pulled upwardly with increasing thickness in order to keep the growth conditions at the growth front 118 at the lower end of the crystal always the same.

If very long crystals are to be pulled, it is recommended that the crystal should not be greatly cooled at the upper end when the crystal is being pulled upwardly in order to avoid stresses which can lead to dislocations and cracks. That can be implemented by the reactor or the gas outlet 120 being of a suitably long configuration and by heating of the region in question.

An advantage of the hanging structure of the crystal holder 114, as shown in FIG. 1, is the avoidance of parasitic depositions on the crystal 112. When other geometries are involved, falling deposits which occur on the reactor walls can give rise to parasitic depositions of that kind.

The material of the reactor chamber can be for example quartz glass. When quartz glass is used however the growing layer on the reactor wall also tears away the glass, which entails complete destruction of the reactor. The deposits however can be reduced by the introduction of the inert gases or hydrogen along the reactor wall. What is preferred in relation to quartz glass however is the use of boron nitride (BN) as that material makes it possible to remove deposits without destruction of the boron nitride.

Above all boron nitride is also ideally suited as the material for the melting crucible A because it can be produced at a high level of purity, it is stabilised by the nitrogen precursor and causes only little trouble as a trace impurity in the resulting GaN or AlGaN single crystals. Alternatively however it is also possible to use any other high temperature-resistant material which does not decompose at the temperatures and gas atmospheres used. Besides quartz glass that is also the materials tantalum carbide TaC, silicon carbide SiC and carbon C. When using graphite in a hydrogen atmosphere, a coating with silicon carbide SiC is recommended.

In the embodiment of FIG. 1 residual gases issue at the upper end of the reactor where a pump (not shown) can be mounted to produce a reduced pressure or a controllable throttle valve (also not shown) can be mounted to produce an increased pressure.

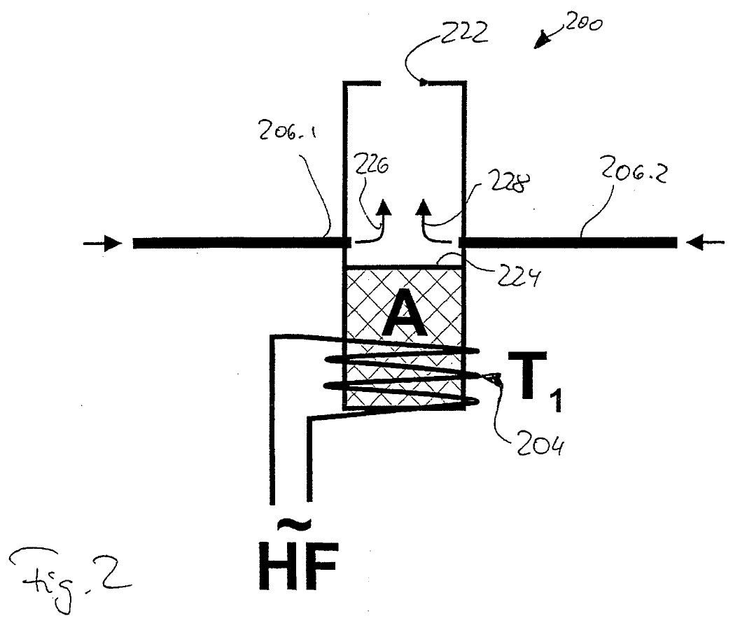

FIG. 2 shows a first variant of a melting crucible 200 for use in the reactor arrangement of FIG. 1 instead of the melting crucible A. Apart from the carrier gas feeds 206.1 and 206.2 and a carrier gas outlet opening 222 the melting crucible 200 is closed on all sides. Unlike the embodiment of FIG. 1 therefore in this case the carrier gas feeds 206.1 and 206.2 are passed directly into the melting crucible 200. A volume for providing a vertical gas flow, indicated by arrows 226 and 228, is afforded above the surface 224 of the metal melt, by virtue of the melting crucible 200 being of an elongate configuration. The very substantially closed configuration of the melting crucible 200 promotes the avoidance of pre-reactions of the nitrogen precursor (for example ammonia) with the melting melt. The resulting limitation of the gas flow to the diameter of the melting crucible 200 gives rise to a high flow speed for the carrier gas flow which counteracts diffusion of the nitrogen precursor into the melt still more efficiently than the example shown in FIG. 1. At the same time the increased flow speed provides for efficient transport of the gallium vapour into the reactor chamber.

In principle it would also be possible to provide solely for an elongate configuration for the melting crucible and not to provide a separate cover in an upward direction. However that variant would not be as efficient as the reduction in the diameter of the outlet opening, as shown in FIG. 2.

The embodiment of FIG. 2 shows the crucible 200 with the carrier gas feeds 206.1 and 206.2 as well as the lines of a high frequency heating means 204. When such a crucible structure is adopted it is advantageous for the upper portions of the wall to be kept at the same temperature as or at a higher temperature than the temperature of the melt. That can be effected for example by using an induction heating means by virtue of a suitable configuration for the coils and thus the high frequency field or by an additional resistance heating means.

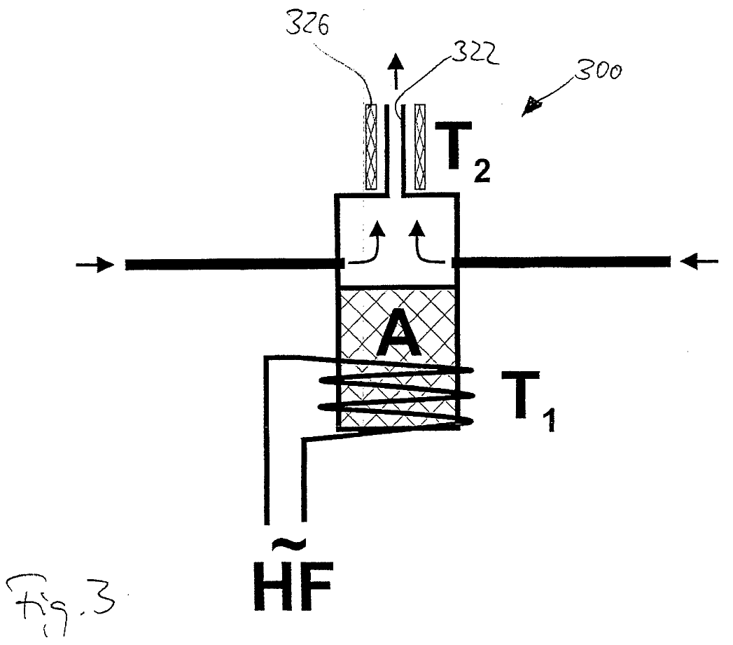

FIG. 3 shows a variant of a melting crucible 300 which shows an implementation of that concept. The melting crucible 300 is the same as the melting crucible 200 except for the differences referred to hereinafter. Instead of the opening 222, there is a thin outlet tube 322 at the upper end of the melting crucible, through which the gallium vapour issues with the flushing gas. A heating means 326 surrounds the outlet tube 322. To avoid deposits and to reduce the risk of gallium droplet formation in the gas flow, the wall of the outlet tube 322 should be heated to a temperature T₂>T₁.

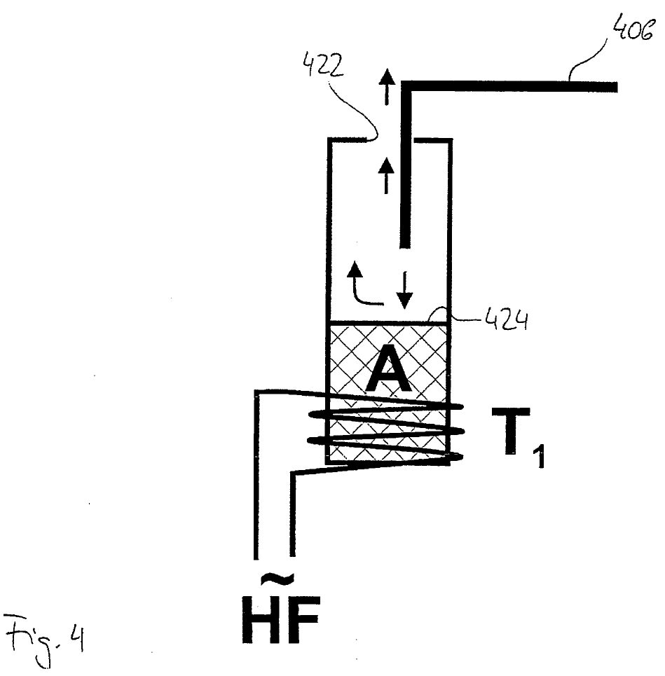

FIG. 4 shows a further variant in the form of a melting crucible 400 in which a feed 406 for the carrier gas is implemented through an opening 422 provided at the top side of the melting crucible. The melting crucible is otherwise the same as the melting crucible 200 in FIG. 2. The carrier gas feed shown in FIG. 4 also produces a gas flow which is passed directly over the surface 424 of the metal melt, is then guided upwardly together with the issuing gallium vapour and is passed out of the outlet opening 422 in the direction of the reaction region. There is accordingly no need for the carrier or flushing gas to be introduced in parallel relationship with the surface 424 of the metal melt in order to prevent contact of the surface thereof with the nitrogen precursor. Introduction in perpendicular relationship to the surface achieves the same effect.

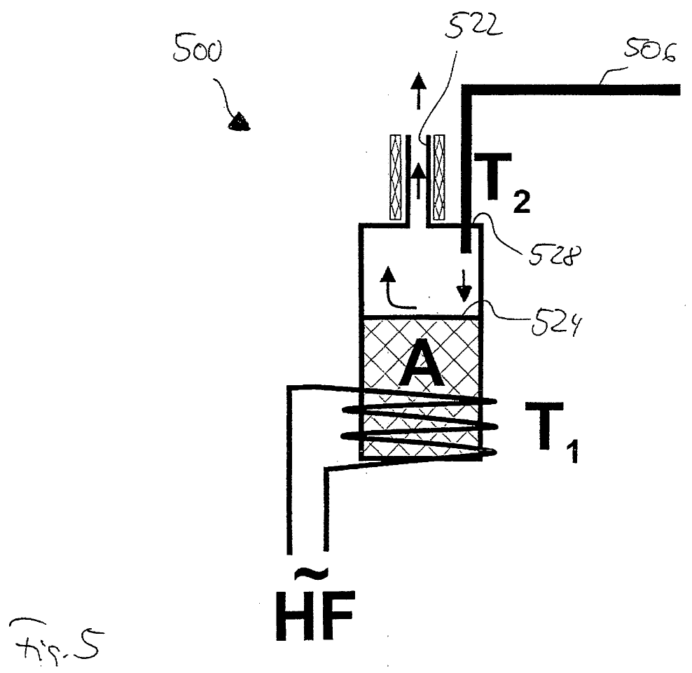

FIG. 5 shows as a further variant a melting crucible 500 which combines together the characteristics of the melting crucibles 300 and 400 (see FIGS. 3 and 4). In this embodiment the carrier gas is introduced by way of a carrier gas feed 506 at the top side 528 of the melting crucible 500. Accordingly the gas flow firstly faces downwardly as in the example of FIG. 4, then impinges against the metal surface 524 in order from there to rise upwardly together with the issuing metal vapour and to be passed into the reactor chamber through an outlet tube 522.

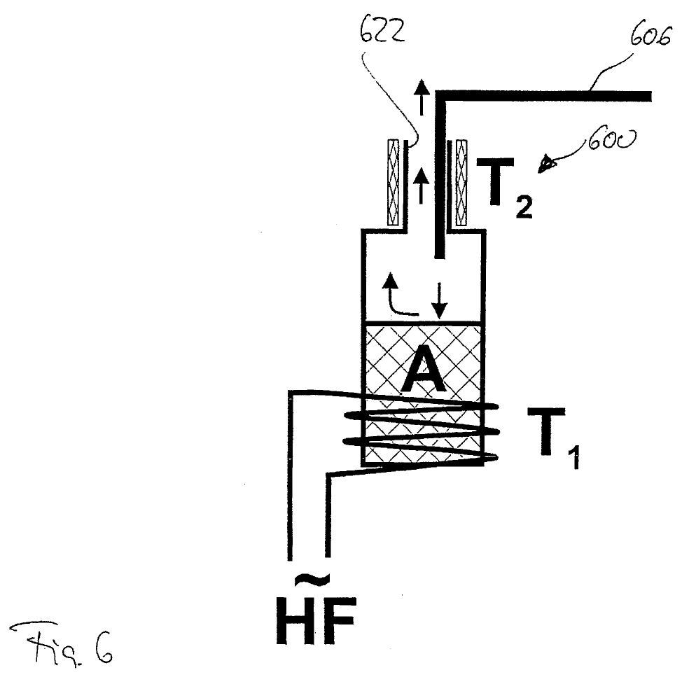

FIG. 6 shows a further variant of a melting crucible 600 in which the outlet tube 622 is increased in width in order to also accommodate the carrier gas feed 606.

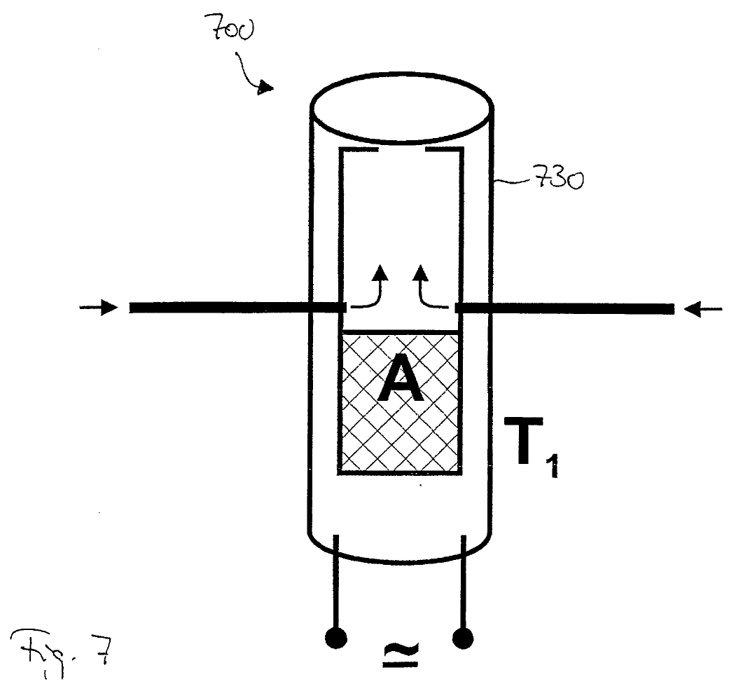

FIG. 7 shows a further variant of a melting crucible 700 in which a tubular heating means 730 is used instead of a high frequency heating means. Otherwise the structure of the melting crucible is the same as that shown in FIG. 2.

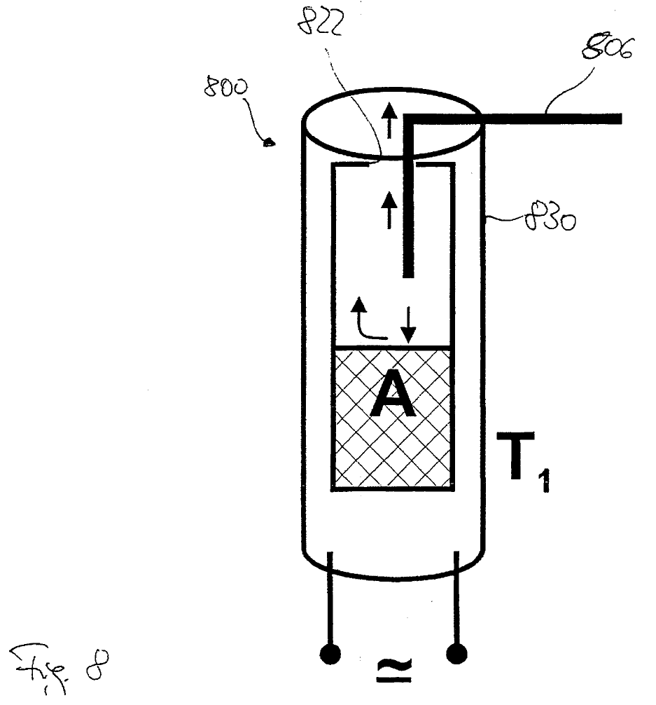

FIG. 8 shows a further variant in the form of a melting crucible 800 in which, similarly to the case with the embodiment shown in FIG. 4, the carrier gas feed 806 is passed through the outlet opening 822 at the top side of the melting crucible. A tubular heating means 830 is used similarly to the case with the embodiment of FIG. 7.

In the case of the melting crucibles in FIGS. 4, 5, 6 and 8 in an alternative configuration the carrier gas feed can be passed into the metal melt so that the carrier gas rises in bubble form in the metal melt and issues from the metal melt. That embodiment can also be combined with those described hereinbefore so that both a carrier gas flow can be passed on to the surface of the metal melt and can also be passed thereinto.

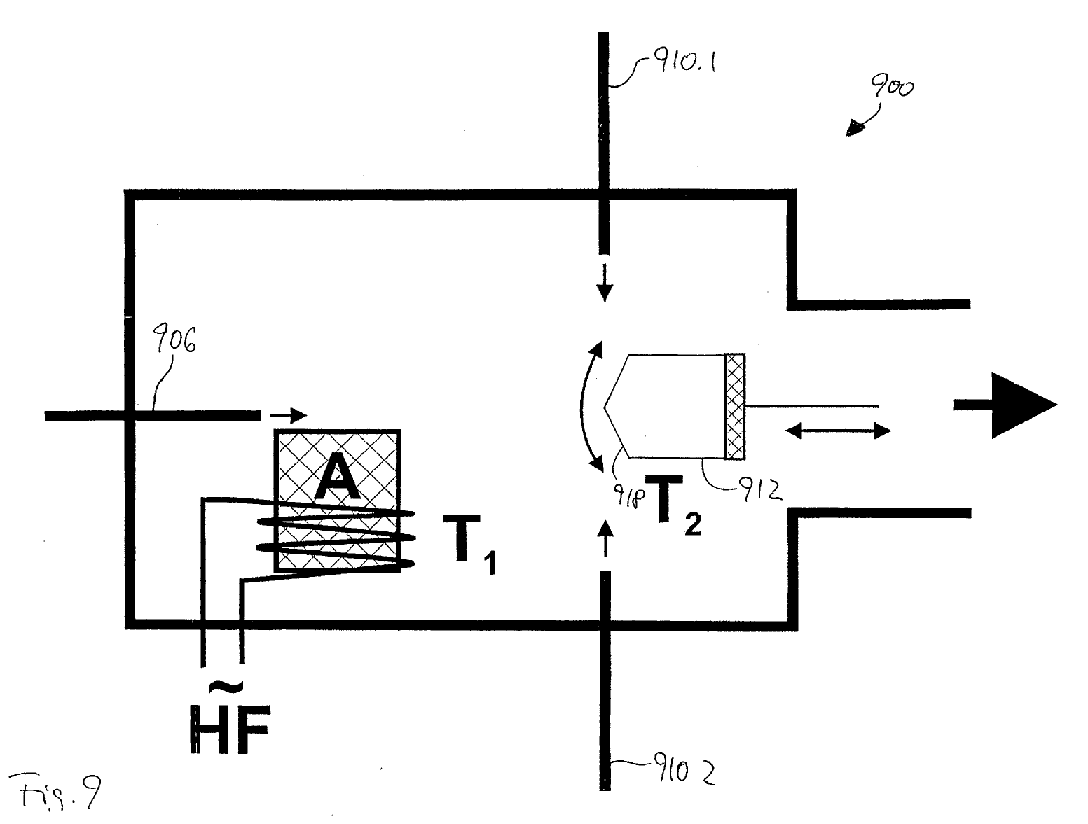

FIG. 9 shows an alternative configuration of a reactor chamber 900. The difference in relation to the reactor chamber 100 in FIG. 1 is that this is a horizontal arrangement. The melting crucible A and the carrier gas feed 906 are arranged in a corresponding fashion. In this case also only one carrier gas line is also sufficient as the horizontal gas flow, after having been passed over the surface of the metal melt in the melting crucible A, is further guided in the direction of the growing crystal 912 on to the growth surface 918 thereof. In this embodiment the feed of the precursor gas is in a vertical direction through precursor feed lines 910.1 and 910.2. In other respects the mode of operation of the reactor arrangement 900 is similar to that described with reference to FIG. 1.

It will be appreciated that the process according to the invention can also be used for the production of polycrystalline crystals.

What is claimed is:

1. A process for the production of a gallium nitride crystal or an aluminium gallium nitride crystal comprising the steps:
providing a metal melt of pure gallium or a mixture of aluminium and gallium in a melting crucible;
vaporisation of gallium or gallium and aluminium out of the metal melt;
decomposing a nitrogen precursor by thermal effect or by means of a plasma; and
causing single-crystalline crystal growth of a GaN or AlGaN crystal on a seed crystal under a pressure of less than 10 bars;
in which
the vaporisation of gallium or gallium and aluminium is effected at a temperature above the temperature of the growing crystal but at least at 1000° C., and in which
a gas flow of nitrogen gas, hydrogen gas, inert gas or a combination of those gases is passed over the metal melt surface in such a way that the gas flow over the metal melt surface prevents contact of the nitrogen precursor with the metal melt.

2. A process according to claim 1 in which
the metal melt is provided in a reactor chamber in a melting crucible vessel which, apart from at least one carrier gas feed and at least one carrier gas outlet opening, is closed on all sides, and in which
the gas flow is introduced into the melting crucible vessel through the carrier gas feed above the metal melt and transported with metal vapour of the metal melt out of the melting crucible vessel through the carrier gas outlet opening, and
the nitrogen precursor is introduced into the reactor chamber in a reaction region.

3. A process according to claim 1 in which
the provision of the metal melt includes arranging the melting crucible in a reactor chamber,
the gas flow is introduced into the reactor chamber through a carrier gas feed slightly above the metal melt, and
the nitrogen precursor is introduced into the reactor chamber in a reaction region.

4. A process according to claim 2 in which the gas flow is introduced either into the melting crucible vessel or the reactor chamber in a direction in parallel relationship with the surface of the metal melt.

5. A process according to claim 2 in which the gas flow is introduced either into the melting crucible vessel or the reactor chamber in a direction in perpendicular relationship with the surface of the metal melt.

6. A process according to claim 1 in which the vaporisation of gallium or gallium and aluminium is effected at a temperature of at least 1100° C.

7. A process according to claim 2 in which a gaseous dopant precursor is introduced into the reaction region.

8. A process according to claim 2 in which a dopant is provided in the form of a melt or a solid in the reactor chamber and is vaporised or sublimated.

9. A process according to claim 1 in which the seed crystal or the growing crystal rotates while the single-crystalline crystal growth is being brought about.

10. A process according to claim 2 in which the gas flow contains hydrogen or consists of hydrogen and the provision of the metal melt in a melting crucible includes the use of a melting crucible of boron nitride BN, tantalum carbide TaC, silicon carbide SiC, quartz glass or carbon or a combination of two or more of said materials.

11. A reactor arrangement for the production of a gallium nitride crystal or a gallium aluminium nitride crystal, comprising
a device for feeding a nitrogen precursor into a reaction region of a reactor chamber,
a device for decomposition of the nitrogen precursor in the reaction region by thermal action or by means of a plasma,
a melting crucible for receiving a metal melt of pure gallium or a mixture of aluminium and gallium,
a first heating device which is adapted to set the temperature of the metal melt in the melting crucible to a value above the temperature of the growing crystal but at least at 1000° C.,
a carrier gas source which is adapted to deliver nitrogen gas, hydrogen gas, inert gas or a combination of said gases, and
at least one carrier gas feed which is connected to the carrier gas source and which is arranged and adapted to pass a gas flow over the metal melt surface in such a way that the gas flow prevents contact of the nitrogen precursor with the metal melt.

12. A reactor arrangement according to claim 11 in which the melting crucible is in the form of a melting crucible vessel which apart from the carrier gas feed and at least one carrier gas outlet opening is closed on all sides and in which the carrier gas feed is arranged above the surface of the metal melt.

13. A reactor arrangement according to claim 12 in which the first heating device is adapted to heat the walls of the melting crucible vessel above the metal melt to a higher temperature than in the region of the metal melt.

14. A reactor arrangement according to claim 13 in which the carrier gas outlet opening forms the end of a tubular outlet and in which there is provided a second heating device which is adapted to heat the walls of the outlet to a higher temperature than the first heating device heats the walls of the melting crucible vessel in the region of the metal melt.

15. A reactor arrangement according to claim 12 in which the carrier gas feed is adapted to introduce a gas flow into the melting crucible vessel or the reactor chamber in a direction in parallel relationship with the surface of the metal melt.

16. A reactor arrangement according to claim 12 in which the reactor chamber has an introduction opening for introducing a seed crystal into the reaction region.

17. A reactor arrangement according to claim 11 in which the melting crucible is made from boron nitride BN, tantalum carbide TaC, silicon carbide SiC, quartz glass or carbon, or a combination of two or more of said materials.

18. A reactor arrangement according to claim 11 comprising a holding means for the seed crystal, which is adapted to rotate the seed crystal during the crystal growth.

19. A reactor arrangement according to claim 11 comprising a second melting crucible which is adapted to receive an aluminium melt.
